(19) United States
(12) Patent Application Publication
(10) Pub. No.: US 2012/0112181 A1
(43) Pub. Date: May 10, 2012

(54) OXIDE SEMICONDUCTOR, THIN FILM TRANSISTOR INCLUDING THE SAME AND THIN FILM TRANSISTOR DISPLAY PANEL INCLUDING THE SAME

(75) Inventors: Je-Hun LEE, Seoul (KR); Joo-Han KIM, Yongin-si (KR); Byung-Du AHN, Hwaseong-si (KR); Sang Wook KIM, Yongin-si (KR); Jae Woo PARK, Seongnam-si (KR); Chang Jung KIM, Yongin-si (KR)

(73) Assignee: SAMSUNG ELECTRONICS CO., LTD., Suwon-si (KR)

(21) Appl. No.: 13/103,593

(22) Filed: May 9, 2011

(30) Foreign Application Priority Data
May 11, 2010 (KR) 10-2010-0043960

(51) Int. Cl. H01L 29/12

(52) U.S. Cl. 257/43; 257/E29.068

(57) ABSTRACT

An oxide semiconductor including: (A) at least one element of zinc (Zn) and tin (Sn); and (B) at least one element of arsenic (As), antimony (Sb), chromium (Cr), cerium (Ce), tantalum (Ta), neodymium (Nd), niobium (Nb), scandium (Sc), yttrium (Y), and hafnium (Hf), is provided.

### CROSS REFERENCE TO RELATED APPLICATION

This application claims priority from and the benefit of Korean Patent Application No. 10-2010-0043960, filed on May 11, 2010, which is hereby incorporated by reference for all purposes as if fully set forth herein.

### BACKGROUND OF THE INVENTION

1. Field of the Invention

Exemplary embodiments of the present invention relate to an oxide semiconductor, a thin film transistor including the same, and a thin film transistor array panel including the same.

2. Discussion of the Background

Flat panel displays such as a liquid crystal display (LCD), an organic light emitting diode (OLED) display, an electrophoretic display, a plasma display, and the like include multiple pairs of electric field generating electrodes and an electro-optical active layer interposed therebetween. The LCD includes a liquid crystal layer as the electro-optical active layer, and the OLED display includes an organic light emitting layer as the electro-optical active layer. One out of a pair of electric field generating electrodes is generally connected to a switching element to receive an electric signal, and the electro-optical active layer converts the electric signal into an optical signal to display an image.

The flat panel display may include a display panel having a thin film transistor. The thin film transistor array panel is patterned with multiple electrodes and semiconductors, and masks are generally used in the patterning process.

On the other hand, the semiconductor is an important factor in determining the characteristics of the thin film transistor. The semiconductor is generally made of amorphous silicon, however the charge mobility thereof is low such that there is a limit in manufacturing a high performance thin film transistor. In the case of using a polysilicon as the semiconductor, the charge mobility is high such that the manufacturing of the high performance thin film transistor is easy, however the cost is high and uniformity is low such that there is a limit in manufacturing a large-sized thin film transistor array panel.

Accordingly, a thin film transistor using an oxide semiconductor having high charge mobility and a high ON/OFF ratio of current compared with amorphous silicon and having a low cost and high uniformity compared with the polysilicon has been researched.

As the oxide semiconductor, GIZO (Ga—In—Zn oxide) including indium oxide (InOx), gallium oxide (GaOx), and zinc oxide (ZnOx) has been researched. However, the cost of indium and gallium is high compared with zinc and tin.

The above information disclosed in this Background section is only for enhancement of understanding of the background of the invention and therefore it may contain information that does not form any part of the prior art.

### SUMMARY OF THE INVENTION

Exemplary embodiments of the present invention provide a thin film transistor array panel including a thin film transistor having an oxide semiconductor that exhibits improved charge mobility and improved stability that can improve thin film transistor characteristics, and be manufactured at a relatively low cost.

Additional features of the invention will be set forth in the description which follows, and in part will be apparent from the description, or may be learned by practice of the invention.

An exemplary embodiment of the present invention discloses an oxide semiconductor including a component (A) having at least one element selected from the group of zinc (Zn) and tin (Sn); and including a component (B) having at least one element selected from the group of arsenic (As), antimony (Sb), chromium (Cr), cerium (Ce), tantalum (Ta), neodymium (Nd), niobium (Nb), scandium (Sc), yttrium (Y), and hafnium (Hf). An atomic concentration ratio of component (B) to (component (A)+component (B)) is about 0.01 to about 20, and an oxide formation Gibbs free energy of the component (B) is greater than or equal to about −260 Kcal/mol and less than or equal to about −80 Kcal/mol.

An exemplary embodiment of the present invention also discloses an oxide semiconductor that includes a component (A) including zinc-tin oxide; and a component (B) including at least one element selected from the group of arsenic (As) and antimony (Sb).

In an embodiment, the atomic concentration ratio of zinc to tin may be about ⅓ to about 3. In an embodiment, the atomic concentration ratio of component (B) to (component (A)+component (B)) may be about 0.01 to about 20. In an embodiment, the oxide semiconductor may further include component (C) having at least one element selected from the group of chromium (Cr), cerium (Ce), tantalum (Ta), neodymium (Nd), niobium (Nb), scandium (Sc), yttrium (Y), hafnium (Hf), or combinations thereof. In an embodiment, the atomic concentration ratio of (component (B)+component (C)) to (component (A)+component (B)+component (C)) may be about 0.01 to about 20. In an embodiment, the oxide semiconductor may only include component (A) and component (B).

An exemplary embodiment of the present invention also discloses an oxide semiconductor that includes a component (A) having zinc oxide; and a component (B) having at least one element selected from the group of arsenic (As), antimony (Sb), chromium (Cr), cerium (Ce), neodymium (Nd), niobium (Nb), scandium (Sc), and hafnium (Hf).

In an embodiment, an atomic concentration ratio of component (B) to (component (A)+component (B)) may be about 0.01 to about 20. In an embodiment, the oxide semiconductor may further include component (C) having at least one element selected from the group of tantalum (Ta), yttrium (Y) or combinations thereof. In an embodiment, an atomic concentration ratio of (component (B)+component (C)) to (component (A)+component (B)+component (C)) may be about 0.01 to about 20. In an embodiment, the oxide semiconductor may only include component (A) and component (B).

An exemplary embodiment of the present invention also discloses an oxide semiconductor that includes a component (A) having tin oxide; and a component (B) having at least one element selected from the group of arsenic (As), antimony (Sb), chromium (Cr), cerium (Ce), tantalum (Ta), neodymium (Nd), niobium (Nb), scandium (Sc), yttrium (Y), and hafnium (Hf).

An exemplary embodiment of the present invention also discloses a thin film transistor including a gate electrode; a source electrode; a drain electrode disposed with the same layer as the source electrode; an oxide semiconductor disposed between the gate electrode and the source electrode; and a gate insulating layer disposed between the gate electrode and the source electrode. The oxide semiconductor includes: a component (A) having at least one element selected from the group of zinc (Zn) and tin (Sn); and a component (B) having at least one element selected from the group of arsenic (As), antimony (Sb), chromium (Cr), cerium (Ce), tantalum (Ta), neodymium (Nd), niobium (Nb), scandium (Sc), yttrium (Y), and hafnium (Hf).

An exemplary embodiment of the present invention also discloses a thin film transistor array panel that includes a substrate. A gate line is disposed on the substrate and includes a gate electrode. A gate insulating layer is disposed on the gate line. An oxide semiconductor is disposed on the gate insulating layer. A data line is disposed on the oxide semiconductor and includes a source electrode. A drain electrode faces the source electrode and is spaced apart from the source electrode on the oxide semiconductor, and a passivation layer is disposed on the data line. The oxide semiconductor includes a component (A) having at least one element selected from the group of zinc (Zn) and tin (Sn); and a component (B) having at least one element selected from the group of arsenic (As), antimony (Sb), chromium (Cr), cerium (Ce), tantalum (Ta), neodymium (Nd), niobium (Nb), scandium (Sc), yttrium (Y), and hafnium (Hf).

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a cross-sectional view of a thin film transistor according to an exemplary embodiment of the present invention.

FIG. 2 is a cross-sectional view of a thin film transistor according to an exemplary embodiment of the present invention.

FIG. 3 is a top plan view of a thin film transistor array panel according to an exemplary embodiment of the present invention.

FIG. 4 is a cross-sectional view of the thin film transistor array panel of FIG. 3 taken along line II-II.

FIG. 5 is a cross-sectional view of a liquid crystal display according to an exemplary embodiment of the present invention.

FIG. 6 is a cross-sectional view of a liquid crystal display according to an exemplary embodiment of the present invention.

### DETAILED DESCRIPTION OF THE ILLUSTRATED EMBODIMENTS

The present invention will be described more fully hereinafter with reference to the accompanying drawings, in which exemplary embodiments of the present invention are shown. As those skilled in the art would realize, the described embodiments may be modified in various different ways, all without departing from the spirit or scope of the present invention. In the drawings, irrelevant portions are omitted to clearly describe the present invention, and like reference numerals designate like elements throughout the specification. Furthermore, detailed descriptions are not given to the well-known arts.

In the drawings, the thickness of layers, films, panels, regions, etc., may be exaggerated for clarity. It will be understood that when an element such as a layer, film, region, or substrate is referred to as being “on” or “connected to” another element, it can be directly on or directly connected to the other element or intervening elements may also be present. In contrast, when an element is referred to as being “directly on” or “directly connected to” another element, there are no intervening elements present. It will be understood that when an element such as a layer, film, region, or substrate is referred to as being “under” another element, it can be directly under the other element or intervening elements may also be present. On the contrary, when an element is referred to as being “directly under” another element, there are no intervening elements present.

Now, an oxide semiconductor according to an exemplary embodiment of the present invention will be described.

The oxide semiconductor includes at least one of zinc (Zn), tin (Sn) or a combination thereof. The oxide semiconductor may include zinc oxide, tin oxide, zinc-tin oxide, or a combination thereof. The oxide semiconductor does not include indium (In) or gallium (Ga), or may include a small amount thereof. The cost of zinc and tin is very low compared with indium and gallium such that the cost of the oxide semiconductor may be low. For example, the cost of indium and gallium are about $918K/ton and about $443K/ton, respectively, and the cost of zinc and tin are about $3.5K/ton and about $12.5K/ton, respectively.

In the case of the oxide semiconductor including zinc and tin, an atomic concentration ratio of zinc to tin may be about ⅓ to about 3. When the atomic concentration ratio of zinc to tin is more than about ⅓ and less than about 3, an etching speed of the oxide semiconductor may be optimized. Also, the oxide formation Gibbs free energy of tin is greater than that of zinc, indium, and gallium such that a generation of an oxygen vacancy may be reduced in the case of a tin-zinc oxide semiconductor, and thereby improving stability of the oxide semiconductor and improving a characteristic of a thin film transistor including the oxide semiconductor. When the absolute value of the oxide formation Gibbs free energy is large, it means that there is a strong combination force between the corresponding element and oxygen. Also, the oxide semiconductor is formed by a combination of a metal and oxygen, and two electrons functioning as a carrier may be generated when an oxygen escapes from the oxide semiconductor generating an oxygen vacancy. Also, a DOS (density of state) of the oxide semiconductor may increase when the oxygen vacancy is generated. The DOS means a density of the state in which electrons may occupy an arbitrary energy region. Finally, when the magnitude of the oxide formation Gibbs free energy of the metal elements forming the oxide semiconductor is large, the oxygen vacancy generation may be reduced, and thereby the stability of the oxide semiconductor may be improved.

The oxide semiconductor may further include at least one other element having oxide formation Gibbs free energy of more than a predetermined value as well as zinc or tin. For example, the at least one other element can be arsenic (As), antimony (Sb), chromium (Cr), cerium (Ce), tantalum (Ta), neodymium (Nd), niobium (Nb), scandium (Sc), yttrium (Y), hafnium (Hf) or a combination thereof. When one or more of these elements are included in the oxide semiconductor, the oxygen vacancy generation may be reduced in the oxide semiconductor such that the stability of the oxide semiconductor or the characteristic of the thin film transistor including the oxide semiconductor may be improved. The oxide formation Gibbs free energy of the other elements may be greater than or equal to about −260 Kcal/mol and less than or equal to about −80 Kcal/mol, and in this case, the stability of the oxide semiconductor may be optimized. The atomic concentration ratio of the other element for the entire metal element of the oxide semiconductor may be about 0.01 to about 20, and in this case, the charge mobility and the stability of the oxide semiconductor may be optimized.

The oxide formation Gibbs free energy for each metal element may be summarized as in the following Table 1. Here, the oxide formation Gibbs free energy calculates a reaction energy for oxygen per 1 mol of each metal at about 100° C.

TABLE 1

| Bond type | ΔGf (Kcal/mol) |
|---|---|
| Zn—O | −84 |
| Sn—O | −138 |
| As—O | −110 |
| Sb—O | −116 |
| Cr—O | −136 |
| Ce—O | −214 |
| Ta—O | −224 |
| Nd—O | −226 |
| Nb—O | −227 |
| Sc—O | −228 |
| Y—O | −228 |
| Hf—O | −257 |

An exemplary embodiment of the oxide semiconductor may only include zinc-tin oxide and arsenic, or may only include zinc-tin oxide and antimony, and in this case, indium and gallium may not be included. An exemplary embodiment of the oxide semiconductor may only include one of arsenic, antimony, chromium, cerium, neodymium, niobium, scandium, and hafnium and zinc oxide, in this case, tin, indium, and gallium may not be included. An exemplary embodiment of the oxide semiconductor may only include one of arsenic, antimony, chromium, cerium, tantalum, neodymium, niobium, scandium, yttrium, and hafnium as well as tin, and in this case, zinc, indium, and gallium may not be included.

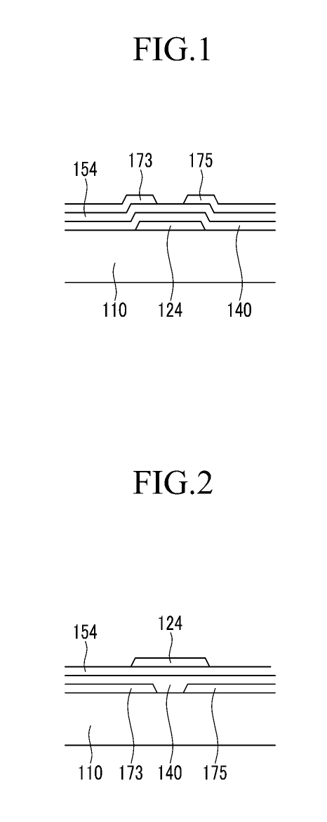

Next, a thin film transistor according to an exemplary embodiment of the present invention will be described with reference to FIG. 1.

FIG. 1 is a cross-sectional view of a thin film transistor according to an exemplary embodiment of the present invention.

A first substrate 110 is provided. The first substrate 110 may be insulated, and may include plastic or glass.

A gate electrode 124 is disposed on the first substrate 110. The gate electrode 124 may include an aluminum-based metal of aluminum (Al) or an aluminum alloy, a silver-based metal of silver (Ag) or a silver alloy, a copper-based metal of copper (Cu) or a copper alloy such as CuMn, a molybdenum-based metal of molybdenum (Mo) or molybdenum alloy, chromium (Cr), tantalum (Ta), titanium (Ti), etc. and alloys thereof. Also, the gate electrode 124 may include a transparent conductive material such as ITO (indium tin oxide), IZO (indium zinc oxide), and AZO (aluminum doped ZnO). However, the gate electrode 124 may have a multi-layered structure including at least two conductive films (not shown).

A gate insulating layer 140 is disposed on the gate electrode 124. The gate insulating layer 140 may include silicon nitride (SiNx), silicon oxide (SiOx), silicon oxynitride (SiON), or an organic insulating material. The gate insulating layer 140 may have a multi-layered structure including at least two insulating layers (not shown). For example, an upper layer of the gate insulating layer 140 may include SiOx and a lower layer may include SiNx, or the upper layer may include SiOx and the lower layer may include SiON. When the gate insulating layer 140 contacting the oxide semiconductor 154 includes an oxide, degradation of the channel may be prevented.

An oxide semiconductor 154 is formed on the gate insulating layer 140. The oxide semiconductor 154 includes at least one element of zinc, tin or a combination thereof, and at least one of arsenic, antimony, chromium, cerium, tantalum, neodymium, niobium, scandium, yttrium, hafnium or a combination thereof. The oxide semiconductor 154 may include zinc oxide, tin oxide, zinc-tin oxide or a combination thereof. The oxide semiconductor 154 may not include indium and gallium or may include a small amount thereof. Accordingly, the oxide semiconductor 154 includes the metal element of a low cost, the stability may be improved, and the characteristic of the thin film transistor including the oxide semiconductor 154 may be improved. Furthermore, in an exemplary embodiment the oxide semiconductor 154 may include zinc, tin, and arsenic, or zinc, tin, and antimony, and in this case, indium and gallium may not be included. Also, in an exemplary embodiment the oxide semiconductor 154 may include one of arsenic, antimony, chromium, cerium, neodymium, niobium, scandium, and hafnium and zinc, and in this case, tin, indium, and gallium may not be included. Also, in an exemplary embodiment the oxide semiconductor 154 may include one of arsenic, antimony, chromium, cerium, tantalum, neodymium, niobium, scandium, yttrium, and hafnium as well as tin, and in this case, zinc, indium, and gallium may not be included.

A source electrode 173 and a drain electrode 175 are disposed on the oxide semiconductor 154. Ohmic contact layers doped with impurities may not be formed between the oxide semiconductor 154 and the source electrode 173 and the oxide semiconductor 154 and the drain electrode 175.

The source electrode 173 and the drain electrode 175 may include an aluminum-based metal of aluminum (Al) or an aluminum alloy, a silver-based metal of silver (Ag) or silver alloy, a copper-based metal of copper (Cu) or copper alloy such as CuMn, a molybdenum-based metal of molybdenum (Mo) or molybdenum alloy, chromium (Cr), tantalum (Ta), titanium (Ti), etc. and alloys thereof. For example, the molybdenum alloy may include Mo—Nb or Mo—Ti. Also, the source electrode 173 and the drain electrode 175 may include the transparent conductive material such as ITO, IZO, and AZO. The source electrode 173 and the drain electrode 175 may have a multi-layered structure including two conductive films (not shown). Examples thereof are Mo/Al/Mo, Mo/Al, Mo/Cu, CuMn/Cu, and Ti/Cu.

On the other hand, the gate electrode 124, the source electrode 173, and the drain electrode 175 form a thin film transistor (TFT) along with the oxide semiconductor 154, and the channel of the thin film transistor is disposed in the semiconductor 154 between the source electrode 173 and the drain electrode 175.

The oxide semiconductor 154, and the source electrode 173 and drain electrode 175 except for the channel portion may have substantially the same plane shape. The three layers including the gate insulating layer 140, the oxide semiconductor 154, and the source electrode 173 and drain electrode 175 may be sequentially deposited on the whole surface and may be patterned using one mask. However, the oxide semiconductor 154 and the source electrode 173 may be respectively formed by using one separate mask.

Next, the thin film transistor according to an exemplary embodiment of the present invention will be described with reference to FIG. 2. The overlapping description with the above described thin film transistor of FIG. 1 is omitted.

FIG. 2 is a cross-sectional view of a thin film transistor according to an exemplary embodiment of the present invention.

In the thin film transistor of FIG. 2, the gate electrode 124 is disposed on the oxide semiconductor 154, and the source electrode 173 and the drain electrode 175 are disposed under the oxide semiconductor 154, differently from the thin film transistor of FIG. 1. The material, the multi-layered structure, and the oxide semiconductor of each constituent element may be of the same as for the thin film transistor of FIG. 1.

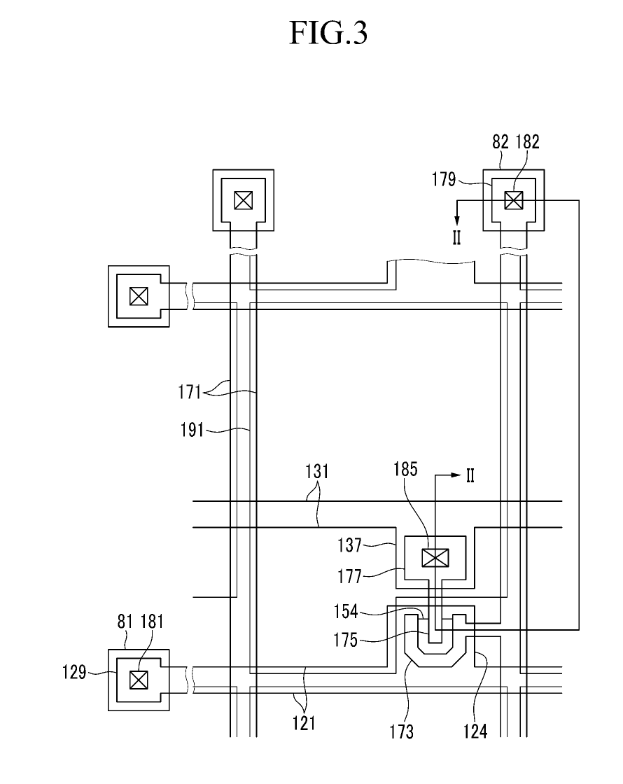

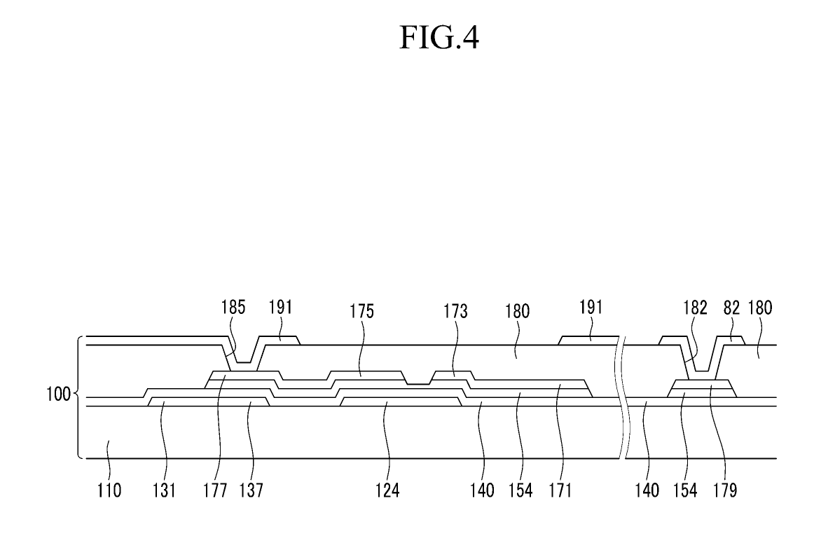

Next, a thin film transistor array panel according to an exemplary embodiment of the present invention will be described with reference to FIG. 3 and FIG. 4. Hereinafter, a thin film transistor array panel applied to a liquid crystal display will be described as an example. However, the thin film transistor array panel may be applied to a flat panel display such as an organic light emitting device.

FIG. 3 is a layout view of a thin film transistor array panel according to an exemplary embodiment of the present invention, and FIG. 4 is a cross-sectional view of the thin film transistor array panel shown in FIG. 3 taken along line II-II.

A gate line 121 (and 129), a gate electrode 124, a storage electrode line 131, and a storage electrode 137 are formed on an insulating substrate 110 including glass or plastic. Each gate line 121 transmitting a gate signal extends in an approximate row direction, and includes a plurality of gate electrodes 124 protruding upward and an end portion 129. However, the end portion 129 of the gate line may be omitted.

The storage electrode line 131 is applied with a predetermined voltage and extends substantially parallel to the gate line 121, and includes the storage electrode 137 with an almost quadrangular shape. Here, the shape and the arrangement of the storage electrode line 131 and the storage electrode 137 may be variously changed. Further, the storage electrode line 131 and the storage electrode 137 may be omitted.

The gate line 121 (and 129) and the storage electrode line 131 may include an aluminum-based metal of aluminum (Al) or aluminum alloy, a silver-based metal of silver (Ag) or silver alloy, a copper-based metal of copper (Cu) or copper alloy such as CuMn, a molybdenum-based metal of molybdenum (Mo) or molybdenum alloy, chromium (Cr), tantalum (Ta), titanium (Ti), etc. and alloys thereof. Also, the gate line 121 (and 129) and the storage electrode line 131 may include a transparent conductive material such as ITO (indium tin oxide), IZO (indium zinc oxide), and AZO (aluminum doped ZnO). However, the gate line 121 (and 129) and the storage electrode line 131 may have a multi-layered structure including two conductive films (not shown).

A gate insulating layer 140 is formed on the gate lines 121 and the storage electrode lines 131. The gate insulating layer 140 may include silicon nitride (SiNx), silicon oxide (SiOx), SiON (silicon oxynitride), or an organic insulating material. The gate insulating layer 140 may have a multi-layered structure including at least two insulating layers (not shown). For example, an upper layer of the gate insulating layer 140 may include SiOx and a lower layer may include SiNx, or the upper layer may include SiOx and the lower layer may include SiON. When the gate insulating layer 140 contacting the oxide semiconductor 154 includes an oxide, degradation of the channel may be prevented.

An oxide semiconductor 154 is disposed on the gate insulating layer 140. The oxide semiconductor 154 includes at least one element of zinc and tin, and at least one of arsenic, antimony, chromium, cerium, tantalum, neodymium, niobium, scandium, yttrium, and hafnium. The oxide semiconductor 154 may not include indium and gallium, or may include a small amount thereof. Accordingly, the oxide semiconductor 154 includes a metal element of low cost, the stability may be improved, and the characteristics of the thin film transistor including the oxide semiconductor 154 may be improved. Furthermore, in an exemplary embodiment the oxide semiconductor 154 may include zinc, tin, and arsenic, or zinc, tin, and antimony, and in this case, indium and gallium may not be included. Also, in an exemplary embodiment the oxide semiconductor 154 may include one of arsenic, antimony, chromium, cerium, neodymium, niobium, scandium, and hafnium, and zinc, and in this case, tin, indium, and gallium may not be included. Also, in an exemplary embodiment the oxide semiconductor 154 may include one of arsenic, antimony, chromium, cerium, tantalum, neodymium, niobium, scandium, yttrium, and hafnium as well as tin, and in this case, zinc, indium, and gallium may not be included.

The channel of the oxide semiconductor 154 may be over-etched in a depth direction. For example, the over-etched thickness in the channel of the oxide semiconductor 154 may be about 50 to about 150 angstroms. However, in an exemplary embodiment the channel of the oxide semiconductor 154 may be not over-etched. The channel of the oxide semiconductor 154 may have at least a predetermined thickness to maintain the characteristics of the thin film transistor. For example, the channel of the oxide semiconductor 154 has a thickness of more than about 300 angstroms.

A data line 171 (and 179) and a drain electrode 175 are disposed on the oxide semiconductor 154. Ohmic contact layers doped with impurities may not be formed between the oxide semiconductor 154 and the data line 171 (and 179). The data line 171 transmits a data voltage and extends in an approximate column direction, thereby crossing the gate line 121. The data line 171 includes an end portion 179, and a source electrode 173 having a curve in a “U” shape on the gate electrode 124. Also, the shape of the source electrode 173 may be variously changed.

The drain electrode 175 is separated from the data line 171, and includes a narrow portion and a wide portion 177. The narrow portion includes an end portion enclosed by the source electrode 173, and the wide portion 177 is almost quadrangular and overlaps the storage electrode 137. The wide portion 177 of the drain electrode 175 may have almost the same area as the storage electrode 137.

The data line 171 (and 179), the source electrode 173, and the drain electrode 175 (and 177) may include an aluminum-based metal of aluminum (Al) or aluminum alloy, a silver-based metal of silver (Ag) or silver alloy, a copper-based metal of copper (Cu) or copper alloy such as CuMn, a molybdenum-based metal of molybdenum (Mo) or molybdenum alloy, chromium (Cr), tantalum (Ta), titanium (Ti), etc. and alloys thereof. For example, the molybdenum alloy may include Mo—Nb or Mo—Ti. Also, the data line 171 (and 179) and the drain electrode 175 (and 177) may include a transparent conductive material such as ITO, IZO, and AZO. The data line 171 (and 179), the source electrode 173, and the drain electrode 175 (and 177) may have a multi-layered structure including two conductive films (not shown) having different physical characteristics. Examples thereof are Mo/Al/Mo, Mo/Al, Mo/Cu, CuMn/Cu, and Ti/Cu.

On the other hand, the gate electrode 124, the source electrode 173, and the drain electrode 175 form a thin film transistor (TFT) along with the oxide semiconductor 154, and the channel of the thin film transistor is formed in the semiconductor 154 between the source electrode 173 and the drain electrode 175. The drain electrode 175 is connected to the pixel electrode 191 thereby applying the driving voltage.

The oxide semiconductor 154, and the data line 171 (and 179) and the drain electrode 175 (and 177) may have substantially the same plane shape. However, the data line 171 (and 179), the source electrode 173, and the drain electrode 175 (and 177) do not cover the channel of the thin film transistor. The three layers including the oxide semiconductor 154, and the data line 171 (and 179) and the drain electrode 177, may be sequentially deposited on the whole surface and may be patterned using one mask. However, the oxide semiconductor 154 and the data line 171 (and 179) may be respectively formed by using one separate mask.

A passivation layer 180 made of silicon nitride (SiNx), silicon oxide (SiOx), or SiON is disposed on the data line 171 (and 179) and the drain electrode 175. The passivation layer 180 may include an organic insulating material. The passivation layer 180 may be multi-layered. For example, an upper layer of the passivation layer 180 may include SiOx and a lower layer may include SiNx, or the upper layer may include SiOx and the lower layer may include SiON. When the passivation layer 180 contacting the oxide semiconductor 154 includes an oxide, degradation of the channel may be prevented. The passivation layer 180 includes a contact hole 185 exposing the drain electrode 177, a contact hole 182 exposing the end portion 179 of the data line, and a contact hole 181 exposing the end portion 129 of the gate line. The pixel electrode 191 is connected to the drain electrode 177 through the contact hole 185. The end portion 179 of the data line is connected to a connecting member 82 through the contact hole 182, and the end portion 129 of the gate line is connected to a connecting member 81 through the contact hole 181.

A pixel electrode 191 is disposed on the passivation layer 180. The pixel electrode 191 may include a transparent conductive oxide such as ITO and IZO. Connecting members 81 and 82 are disposed on the end portions 129 and 179 of the gate line and the data line, respectively. The connecting members 81 and 82 may include the same material as the pixel electrode 191.

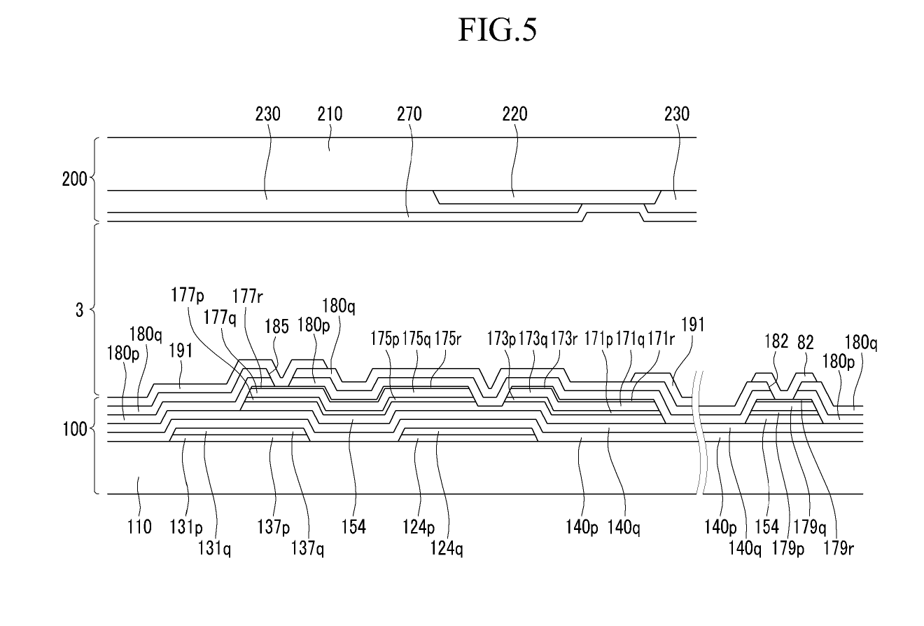

Next, a liquid crystal display according to an exemplary embodiment of the present invention will be described with reference to FIG. 5. However, the overlapping description with the thin film transistor array panel of FIG. 3 and FIG. 4 is omitted.

FIG. 5 is a cross-sectional view of a liquid crystal display according to an exemplary embodiment of the present invention.

A gate electrode (124p and 124q), a storage electrode line (131p and 131q), and a storage electrode (137p and 137q) include a two-layer structure. In other words, gate metals are deposited on the substrate to form the two-layer structure, and then etched through a photolithography process to pattern the gate metal layers. For example, the lower layer of the gate metal layer may be made of Ti, and the upper layer thereof may be made of Cu.

A gate insulating layer of two layers (140p and 140q) is formed on the gate electrode (124p and 124q), the storage electrode line (131p and 131q), and the storage electrode (137p and 137q). For example, the lower layer may be made of SiNx, and the upper layer may be made of SiOx. It is preferable that a portion close to the oxide semiconductor 154 in the gate insulating layer (140p and 140q) is made of an oxide to prevent the characteristic degradation of the channel. Also, the gate insulating layer (140p and 140q) may be made of a single layer of SiON, and in this case, the oxygen concentration of the upper portion 140q may be higher than that of the lower portion 140p. The upper layer of the gate insulating layer 140q may be made of SiOx, and the lower layer thereof 140p made of SiON.

An oxide semiconductor 154 is formed on the gate insulating layer (140p and 140q). The oxide semiconductor 154 may be the same as that in the above-described FIG. 3 and FIG. 4.

A data line (171p, 171q, 171r, 179p, 179q, and 179r), a source electrode (173p, 173q, and 173r), and a drain electrode (175p, 175q, 175r, 177p, 177q, and 177r) including three layers are formed on the oxide semiconductor 154. For example, the three layers may be respectively made of Mo, Al, and Mo. Also, the data line (171p, 171q, 171r, 179p, 179q, and 179r), the source electrode (173p, 173q, and 173r), and the drain electrode (175p, 175q, 175r, 177p, 177q, and 177r) may include two layers of Ti/Cu or CuMn/Cu.

A passivation layer of two layers (180p and 180q) is formed on the data line (171p, 171q, 171r, 179p, 179q, and 179r), the source electrode (173p, 173q, and 173r), and the drain electrode (175p, 175q, 175r, 177p, 177q, and 177r). For example, the lower layer thereof may be made of SiOx, and the upper layer thereof may be made of SiNx. It is preferable that a portion close to the oxide semiconductor in the passivation layer (180p and 180q) is made of an oxide to prevent the characteristic degradation of the channel. Also, the passivation layer (180p and 180q) may be made of the single layer of SiON, and in this case, the oxygen concentration of the upper portion 180q may be higher than that of the lower portion 180p. The lower layer thereof 180p may be made of SiOx, and the upper layer thereof 180q may be made of SiON.

A liquid crystal layer 3 is disposed between the first display panel 100 including the thin film transistors and the second display panel 200 facing the first display panel 100. The liquid crystal layer 3 may have positive or negative dielectric anisotropy, and the liquid crystal molecules of the liquid crystal layer 3 are aligned such that the long axis thereof may be arranged parallel or perpendicular to the surface of the first and second display panels 100 and 200 when no electric field is applied.

At least one alignment layer (not shown) may be formed on an inner surface of at least one of the first and second display panels 100 and 200, and may be a vertical or horizontal alignment layer. At least one polarizer (not shown) may be provided on an outer surface of at least one of the first and second display panels 100 and 200.

A light blocking member 220 is disposed on a second substrate 210. The light blocking member 220 is referred to as a black matrix, and prevents light leakage.

A color filter 230 is disposed on the light blocking member 220. The color filter 230 may have a belt shape between adjacent data lines 171. The color filter 230 may include pigments representing red, green, or blue, and a photosensitive organic material.

A common electrode 270 is formed on the color filter 230. The common electrode 270 may include a transparent conductive oxide such as ITO and IZO.

The pixel electrode 191 is connected to the drain electrode (175p, 175q, and 175r) of the thin film transistor through the contact hole 185, thereby receiving the data voltage from the drain electrode (175p, 175q, and 175r). The pixel electrode 191 to which the data voltage is applied generates an electric field along with the common electrode 270 of the second display panel 200, thereby determining the orientation of liquid crystal molecules of the liquid crystal layer 3 between the electrodes 191 and 270. The luminance of light that passes through the liquid crystal layers is changed according to the orientation of the liquid crystal molecules.

The pixel electrode 191 and the common electrode 270 constitute a liquid crystal capacitor that maintains a voltage applied thereto even after the thin film transistor is turned off.

The pixel electrode 191 and the drain electrode (175p, 175q, and 175r) connected thereto overlap the storage electrode (137p and 137q) and the storage electrode line (131p and 131q) thereby forming a storage capacitor.

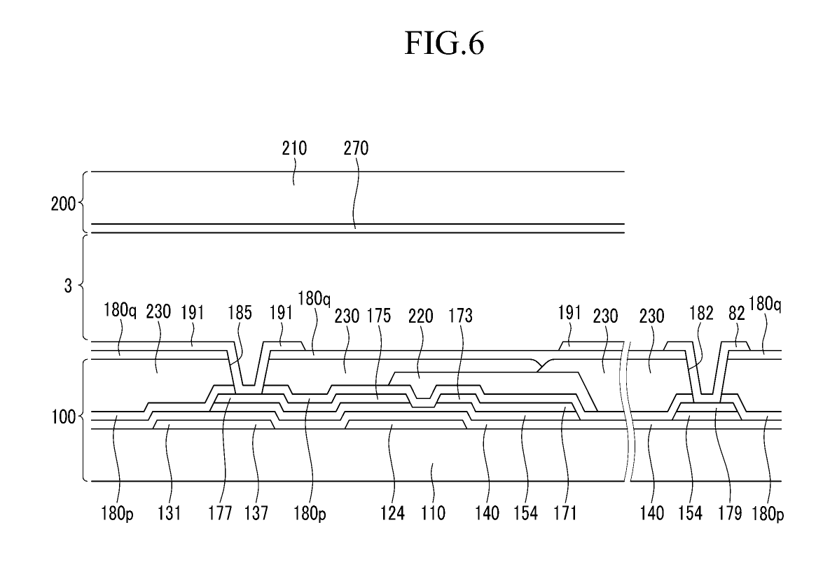

Next, a liquid crystal display according to an exemplary embodiment of the present invention will be described with reference to FIG. 6. However, the overlapping description of the thin film transistor array panel of FIG. 3 and FIG. 4 and the liquid crystal display of FIG. 5 is omitted.

FIG. 6 is a cross-sectional view of a liquid crystal display according to an exemplary embodiment of the present invention.

A light blocking member 220 and a color filter 320 are not disposed in the second display panel 200, but are disposed in the first display panel 100. In other words, the light blocking member 220 is disposed on a lower passivation layer 180p, the color filter 230 is disposed on the light blocking member 220, and the upper passivation layer 180q is disposed on the color filter 230.

Also, in an exemplary embodiment one of the light blocking member 220 and the color filter 230 may be disposed in the first display panel 100, and the other may be disposed in the second display panel 200.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

What is claimed is:

1. An oxide semiconductor, comprising:
a component (A) comprising zinc (Zn), tin (Sn), or both zinc and tin; and
a component (B) comprising arsenic (As), antimony (Sb), chromium (Cr), cerium (Ce), tantalum (Ta), neodymium (Nd), niobium (Nb), scandium (Sc), yttrium (Y), hafnium (Hf), or any combination thereof,
wherein an atomic concentration ratio of component (B) to (component (A)+component (B)) is about 0.01 to about 20, and
an oxide formation Gibbs free energy of the component (B) is in a range of about −260 Kcal/mol to about −80 Kcal/mol.

2. The oxide semiconductor of claim 1, wherein
the oxide semiconductor does not include indium (In) or gallium (Ga).

3. The oxide semiconductor of claim 1, wherein
the component (A) comprises zinc and tin, and the atomic concentration ratio of zinc to tin is in the range of about ⅓ to about 3.

4. An oxide semiconductor, comprising:
a component (A) comprising zinc-tin oxide; and
a component (B) comprising arsenic (As), antimony (Sb), or both arsenic and antimony.

5. The oxide semiconductor of claim 4, wherein
the atomic concentration ratio of zinc to tin is in a range of about ⅓ to about 3.

6. The oxide semiconductor of claim 5, wherein
the atomic concentration ratio of component (B) to (component (A)+component (B)) is about 0.01 to about 20.

7. The oxide semiconductor of claim 4, further comprising
a component (C) comprising chromium (Cr), cerium (Ce), tantalum (Ta), neodymium (Nd), niobium (Nb), scandium (Sc), yttrium (Y), hafnium (Hf), or any combination thereof.

8. The oxide semiconductor of claim 7, wherein
the atomic concentration ratio of (component (B)+component (C)) to (component (A)+component (B)+component (C)) is about 0.01 to about 20.

9. The oxide semiconductor of claim 4, wherein
the oxide semiconductor consists essentially of component (A) and component (B).

10. An oxide semiconductor, comprising:
a component (A) comprising zinc oxide; and
a component (B) comprising arsenic (As), antimony (Sb), chromium (Cr), cerium (Ce), neodymium (Nd), niobium (Nb), scandium (Sc), hafnium (Hf), or any combination thereof.

11. The oxide semiconductor of claim 10, wherein
an atomic concentration ratio of component (B) to (component (A)+component (B)) is about 0.01 to about 20.

12. The oxide semiconductor of claim 10, further comprising
a component (C) comprising tantalum (Ta), yttrium (Y), or both tantalum and yttrium.

13. The oxide semiconductor of claim 12, wherein
an atomic concentration ratio of (component (B)+component (C))/(component (A)+component (B)+component (C)) is about 0.01 to about 20.

14. The oxide semiconductor of claim 10, wherein
the oxide semiconductor consists essentially of component (A) and component (B).

15. An oxide semiconductor, comprising:
a component (A) comprising tin oxide; and
a component (B) comprising arsenic (As), antimony (Sb), chromium (Cr), cerium (Ce), tantalum (Ta), neodymium (Nd), niobium (Nb), scandium (Sc), yttrium (Y), hafnium (Hf), or any combination thereof.

16. The oxide semiconductor of claim 15, wherein
an atomic concentration ratio of component (B) to (component (A)+component (B)) is about 0.01 to about 20.

17. The oxide semiconductor of claim 15, wherein
the oxide semiconductor consists essentially of component (A) and component (B).

18. A thin film transistor, comprising:
a gate electrode;
a source electrode;
a drain electrode spaced apart from the source electrode;
an oxide semiconductor disposed between the gate electrode and the source electrode; and
a gate insulating layer disposed between the gate electrode and the source electrode,
wherein the oxide semiconductor comprises:
a component (A) comprising zinc (Zn), tin (Sn), or both zinc and tin; and
a component (B) comprising arsenic (As), antimony (Sb), chromium (Cr), cerium (Ce), tantalum (Ta), neodymium (Nd), niobium (Nb), scandium (Sc), yttrium (Y), hafnium (Hf), or any combination thereof.

19. The thin film transistor of claim 18, wherein
the gate electrode is disposed under the oxide semiconductor, and the source electrode is disposed on the oxide semiconductor.

20. The thin film transistor of claim 18, wherein
the gate electrode is disposed on the oxide semiconductor, and the source electrode is disposed under the oxide semiconductor.

21. A thin film transistor array panel, comprising:
a substrate;
a gate line disposed on the substrate and comprising a gate electrode;
a gate insulating layer disposed on the gate line;
an oxide semiconductor disposed on the gate insulating layer;
a data line disposed on the oxide semiconductor and comprising a source electrode;
a drain electrode disposed on the oxide semiconductor and spaced apart from the source electrode; and
a passivation layer disposed on the data line,
wherein the oxide semiconductor comprises:
a component (A) comprising zinc (Zn), tin (Sn), or both zinc and tin; and
a component (B) comprising arsenic (As), antimony (Sb), chromium (Cr), cerium (Ce), tantalum (Ta), neodymium (Nd), niobium (Nb), scandium (Sc), yttrium (Y), hafnium (Hf), or any combination thereof.

22. The thin film transistor array panel of claim 21, wherein
the data line, the source electrode, and the drain electrode contact the oxide semiconductor.

23. The thin film transistor array panel of claim 21, wherein
the data line, the source electrode, and the drain electrode each comprise two layers or three layers.

24. The thin film transistor array panel of claim 21, wherein
the gate line and the gate electrode each comprise two layers.

25. The thin film transistor array panel of claim 21, wherein
the gate insulating layer comprises two layers.
